(19) United States
(12) Patent Application Publication
(10) Pub. No.: US 2015/0221517 A1
(43) Pub. Date: Aug. 6, 2015

(54) METHOD OF MANUFACTURING SEMICONDUCTOE DEVICE

(71) Applicant: Samsung Electronics Co., Ltd., Suwon-si (KR)

(72) Inventors: Eun-mi Kim, Yongin-si (KR); Un-byoung Kang, Hwaseong-si (KR); Tae-je Cho, Hwaseong-si (KR); Jung-seok Ahn, Seoul (KR)

(21) Appl. No.: 14/613,822

(22) Filed: Feb. 4, 2015

(30) Foreign Application Priority Data
Feb. 5, 2014 (KR) 10-2014-0013321

(51) Int. Cl. H01L 21/306; H01L 21/768; H01L 21/304; H01L 21/78

(52) U.S. Cl. CPC H01L 21/306; H01L 21/78; H01L 21/76898; H01L 21/304

(57) ABSTRACT

A method of manufacturing a semiconductor device capable of thinning a semiconductor chip can be performed while preventing the semiconductor chip from being damaged. A method of manufacturing a semiconductor device includes: preparing a semiconductor substrate including a plurality of semiconductor chips, attaching the semiconductor substrate to a support substrate with an adhesive support film, removing an edge region of the semiconductor substrate together with a portion of the adhesive support film between the edge region of the semiconductor substrate and the support substrate and, thereafter, polishing the semiconductor substrate to thin the semiconductor substrate.

### CROSS-REFERENCE TO RELATED APPLICATIONS

This application claims the benefit of Korean Patent Application No. 10-2014-0013321, filed on Feb. 5, 2014, in the Korean Intellectual Property Office, the disclosure of which is incorporated herein in its entirety by reference.

### BACKGROUND

Inventive concepts relate to methods of manufacturing semiconductor devices, and more particularly, to methods of manufacturing semiconductor devices including a through-silicon via (TSV).

With continuing rapid development in the electronics industry and, in accordance with user need, electronic apparatus continue to become more highly integrated and made lighter in weight and multifunctional. At the same time, semiconductor devices, on which electronic apparatus are based, are likewise reduced in size and weight. To reduce their size and weight, semiconductor chips that form the semiconductor devices are commonly thinned in a grinding process. As a result of such a grinding process, the semiconductor chips are susceptible to damage, thereby reducing yield.

### SUMMARY

Inventive concepts provide a method of manufacturing a semiconductor device capable of reducing a thickness of a semiconductor chip while preventing damage to the semiconductor chip.

According to an aspect of the inventive concepts, there is provided a method of manufacturing a semiconductor device comprises: preparing a semiconductor substrate including a plurality of semiconductor chips, attaching the semiconductor substrate to a support substrate with an adhesive support film, removing an edge region of the semiconductor substrate together with a portion of the adhesive support film between the edge region of the semiconductor substrate and the support substrate and, after removing the edge region of the semiconductor substrate, polishing the semiconductor substrate to thin the semiconductor substrate.

The adhesive support film may comprise a base film and a first adhesive layer and a second adhesive layer respectively attached to upper and lower surfaces of the base film, the semiconductor substrate may be attached to the first adhesive layer of the adhesive support film, and wherein, in removing of the edge region of the semiconductor substrate together with a portion of the adhesive support film between the edge region of the semiconductor substrate and the support substrate, the first adhesive layer of the adhesive support film between the edge region of the semiconductor substrate and the support substrate may be completely removed.

In removing of the edge region of the semiconductor substrate together with a portion of the adhesive support film between the edge region of the semiconductor substrate and the support substrate, a portion of the base film of the adhesive support film between the edge region of the semiconductor substrate and the support substrate may be also removed.

In removing of the edge region of the semiconductor substrate together with a portion of the adhesive support film between the edge region of the semiconductor substrate and the support substrate, at least a portion of the base film may remain on the second adhesive layer of the adhesive support film between the edge region of the semiconductor substrate and the support substrate.

In removing of the edge region of the semiconductor substrate together with a portion of the adhesive support film between the edge region of the semiconductor substrate and the support substrate, the edge region of the semiconductor substrate and the first adhesive layer may be removed using a blade saw method so that an upper surface of the second adhesive layer is not exposed.

An elastic modulus of the base film may be larger than that of the first adhesive layer.

A thickness of the first adhesive layer may be larger than that of the base film.

In the semiconductor substrate, each of the plurality of semiconductor chips may comprise a plurality of through-silicon vias (TSV) that extend from an active surface of the semiconductor substrate to an inner region of the semiconductor substrate, and in attaching of the semiconductor substrate to the support substrate by using the adhesive support film, the semiconductor substrate may be attached to the support substrate so that the active surface of the semiconductor substrate faces the support substrate.

In polishing of the semiconductor substrate to thin the semiconductor substrate, the semiconductor substrate may polished from an opposite surface to the active surface thereof so that the plurality of TSVs are exposed.

Polishing of the semiconductor substrate to thin the semiconductor substrate further may comprise: forming a plurality of rear surface pads respectively corresponding to the plurality of exposed TSVs on the opposite surface to the active surface of the semiconductor substrate; separating the semiconductor substrate from the support substrate; and dividing the semiconductor substrate into the plurality of semiconductor chips by using die cutting.

A thickness of the edge region of the semiconductor substrate may be reduced toward an edge thereof.

According to another aspect of the inventive concepts, there is provided a method of manufacturing a semiconductor device comprise: preparing a semiconductor substrate having a chip region in which a plurality of semiconductor chips are arranged and an edge region that surrounds the chip region; attaching the semiconductor substrate to a support substrate by using an adhesive support film including a base film and a semiconductor substrate adhesive layer and a support substrate adhesive layer respectively attached to upper and lower surfaces of the base film; removing the edge region of the semiconductor substrate and the semiconductor substrate adhesive layer thereunder to expose the base film; and thereafter polishing the semiconductor substrate to thin the semiconductor substrate.

In removing of the edge region of the semiconductor substrate and the semiconductor substrate adhesive layer thereunder to expose the base film, the edge region of the semiconductor substrate and the semiconductor substrate adhesive layer may be removed by using the base film as an etching stop film.

An area of the support substrate may be larger than that of the semiconductor substrate.

The area of the support substrate may be substantially equal to that of the semiconductor substrate, and a thickness of the edge region of the semiconductor substrate and that of an edge region of the support substrate corresponding to the edge region of the semiconductor substrate may be reduced toward an edge of the edge region of the semiconductor substrate and that of the edge region of the support substrate, respectively.

According to another aspect of the inventive concepts, there is provided a method of manufacturing a semiconductor device, comprising: preparing a semiconductor substrate having a chip region in a central region thereof and an edge region in a perimeter region thereof, the edge region surrounding the chip region; attaching the semiconductor substrate to a support substrate using an adhesive support film; removing the edge region of the semiconductor substrate to expose a portion of the adhesive support film, and following removing the edge region, polishing the semiconductor substrate to thin the semiconductor substrate.

The adhesive support film may include a base film, and may further include a semiconductor substrate adhesive layer and a support substrate adhesive layer respectively attached to upper and lower surfaces of the base film.

Removing the edge region of the semiconductor substrate to expose a portion of the adhesive support film may further comprise exposing a portion of the base film.

Removing the edge region of the semiconductor substrate to expose a portion of the adhesive support film may comprise etching the edge region using a portion of the adhesive support film as an etch stop layer.

Following attaching the semiconductor substrate to a support substrate using an adhesive support film, and prior to removing the edge region of the semiconductor substrate to expose a portion of the adhesive support film, a gap may be present at an edge portion between the semiconductor substrate and the adhesive support film.

Removing the edge region of the semiconductor substrate to expose a portion of the adhesive support film may remove the gap.

### BRIEF DESCRIPTION OF THE DRAWINGS

Exemplary embodiments of the inventive concepts will be more clearly understood from the following detailed description taken in conjunction with the accompanying drawings in which:

FIG. 1 is a plan view illustrating a semiconductor substrate according to an embodiment of the inventive concepts;

FIG. 2 is a cross-sectional view illustrating a semiconductor substrate according to an embodiment of the inventive concepts;

FIG. 3 is a cross-sectional view illustrating a process of preparing a support substrate and an adhesive support film, according to an embodiment of the inventive concepts;

FIG. 4 is a cross-sectional view illustrating a process of attaching an adhesive support film to a support substrate, according to an embodiment of the inventive concepts;

FIG. 5 is a cross-sectional view illustrating a process of attaching a semiconductor substrate to a support substrate by using an adhesive support film, according to an embodiment of the inventive concepts;

FIG. 6 is a cross-sectional view illustrating a process of trimming a semiconductor substrate, according to an embodiment of the inventive concepts;

FIG. 7 is a cross-sectional view illustrating a process of polishing a semiconductor substrate to thin the semiconductor substrate, according to an embodiment of the inventive concepts

FIG. 8 is a cross-sectional view illustrating a process of forming rear surface pads on a semiconductor substrate, according to an embodiment of the inventive concepts;

FIG. 9 is a cross-sectional view illustrating a process of trimming a semiconductor substrate, according to a modification of an embodiment of the inventive concepts;

FIG. 10 is a cross-sectional view illustrating a process of attaching a semiconductor substrate to a support substrate by using an adhesive support film, according to another modification of an embodiment of the inventive concepts;

FIG. 11 is a cross-sectional view illustrating a process of trimming a semiconductor substrate, according to another modification of an embodiment of the inventive concepts;

FIG. 12 is a cross-sectional view illustrating semiconductor chips according to an embodiment of the inventive concepts;

FIG. 13 is a cross-sectional view illustrating an aspect of a stacked semiconductor package including a semiconductor device, according to an embodiment of the inventive concepts;

FIG. 14 is a cross-sectional view illustrating another aspect of a stacked semiconductor package including a semiconductor device, according to an embodiment of the inventive concepts;

FIG. 15 is a plan view illustrating a memory module including a semiconductor device, according to an embodiment of the inventive concepts;

FIG. 16 is a block diagram of a system including a semiconductor device, according to an embodiment of the inventive concepts;

FIG. 17 is a view schematically illustrating a structure of a stacked semiconductor package, according to an embodiment of the inventive concepts;

FIG. 18 is a block diagram of a memory card including a semiconductor device according to an embodiment of the inventive concepts; and

FIG. 19 is a view illustrating an electronic system including a semiconductor device, according to an embodiment of the inventive concepts.

### DETAILED DESCRIPTION OF EMBODIMENTS

Inventive concepts will now be described more fully with reference to the accompanying drawings, in which exemplary embodiments of the inventive concepts are shown. The same elements in the drawings are denoted by the same reference numerals and a repeated explanation thereof will not be given. The inventive concepts may, however, be embodied in many different forms and should not be construed as limited to the exemplary embodiments set forth herein. Rather, these embodiments are provided so that this disclosure will be thorough and complete, and will fully convey the scope of the inventive concepts to one of ordinary skill in the art. In the drawings, the thickness of layers and regions are exaggerated for clarity.

It will also be understood that when an element is referred to as being “on” another element, it can be directly on the other element, or intervening elements may also be present. On the other hand, when an element is referred to as being “immediately on” or as “directly contacting” another element, it can be understood that intervening elements do not exist. Other expressions describing a relationship between elements, for example, “between” and “directly between”, may be interpreted like the above.

It will be understood that, although the terms “first”, “second”, etc., may be used herein to describe various elements, these elements should not be limited by these terms. These terms are only used to distinguish one element from another element. For example, a first element may be named a second element and similarly a second element may be named a first element without departing from the scope of the inventive concepts.

Unless otherwise defined, terms “include” and “have” are for representing that characteristics, numbers, steps, operations, elements, and portions described in the specification or a combination thereof. It may be interpreted that one or more other characteristics, numbers, steps, operations, elements, and portions or a combination thereof may be added.

Unless otherwise defined, all terms (including technical and scientific terms) used herein have the same meaning as commonly understood by one of ordinary skill in the art to which this inventive concepts belong.

Hereinafter, embodiments of the inventive concepts will be described in detail with reference to the accompanying drawings.

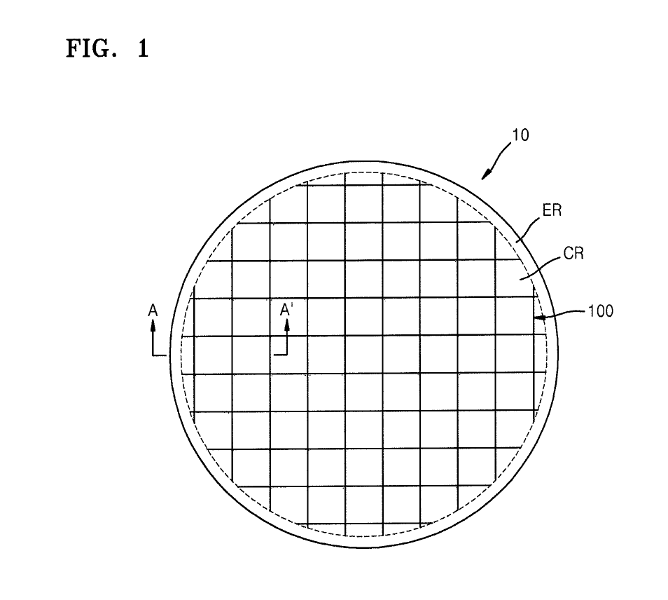

FIG. 1 is a plan view illustrating a semiconductor substrate 10 according to an embodiment of the inventive concepts.

Referring to FIG. 1, the semiconductor substrate 10 includes a plurality of semiconductor chips 100.

The semiconductor substrate 10 may comprise, for example, silicon (Si), a semiconductor element such as germanium (Ge), or a compound semiconductor such as silicon carbide (SiC), gallium arsenide (GaAs), indium arsenide (InAs), and indium phosphide (InP). In some embodiments, the semiconductor substrate 10 may have a silicon on insulator (SOI) structure. For example, the semiconductor substrate 10 may include a buried oxide (BOX) layer. In some embodiments, the semiconductor substrate 10 may include a conductive region, for example, a well doped with impurities or a structure doped with impurities. In addition, the semiconductor substrate 10 may include various isolation structures such as a shallow trench isolation (STI) structure.

In some embodiments, the semiconductor substrate 10 comprise a single-crystal wafer such as a single-crystal silicon wafer formed via a forming method. In other embodiments, the semiconductor substrate 10 comprise various types of wafers such as an epitaxial wafer, a polished wafer, an annealed wafer, and a silicon on insulator (SOI) wafer without being limited to the single crystal wafer. In some embodiments, the epitaxial wafer can be formed by growing a crystal material on a single crystal silicon substrate. The semiconductor substrate 10 may comprise, for example, a wafer having a diameter of 300 mm but is not limited thereto, and can be larger or smaller than 300 mm in diameter.

In some embodiments, the semiconductor substrate 10 may include a chip region CR in which the plurality of semiconductor chips 100 are arranged and an edge region ER that surrounds the chip region CR. The chip region CR is formed inside an edge of the semiconductor substrate 10 to be separate from the edge thereof by a predetermined setback amount. The chip region CR includes a portion of the semiconductor substrate 10, in which the semiconductor chips 100 resultant therefrom can be separated or diced from the semiconductor substrate 10 after semiconductor manufacturing processes are performed, and may function as operable semiconductor devices. The edge region ER adjacent to the edge of the semiconductor substrate 10, which is also referred to as a bevel region or a handling region, refers to a portion of the substrate 10 that does not become operable semiconductor devices.

In some embodiments, the semiconductor chips 100 may include a plurality of various kinds of individual devices. The plurality of individual devices may include various microelectronic devices, for example, a metal-oxide-semiconductor field effect transistor (MOSFET) such as a complementary metal-insulator-semiconductor (CMOS) transistor, an image sensor such as a system large scale integration (LSI) and a CMOS imaging sensor (CIS), a micro-electro-mechanical system (MEMS), an active device, and a passive device. In some embodiments, the plurality of individual devices may be electrically connected to the conductive region of the semiconductor substrate 10. The semiconductor chips 100 may further include conductive wiring lines or conductive plugs for electrically connecting at least two or all of the plurality of individual devices to the conductive region of the semiconductor substrate 10. In addition, the plurality of individual devices may be electrically separated from other adjacent individual devices by insulating films, respectively.

In some embodiments, the semiconductor chips 100 may be seperable from the semiconductor substrate 10 to function as semiconductor devices. In the present specification, the semiconductor chips 100 are referred to in terms of a shape and the semiconductor devices are referred to in terms of a function. However, the semiconductor chips 100 and the semiconductor devices may be combined and used in various applicable configurations that are within contemplation of the present inventive concepts.

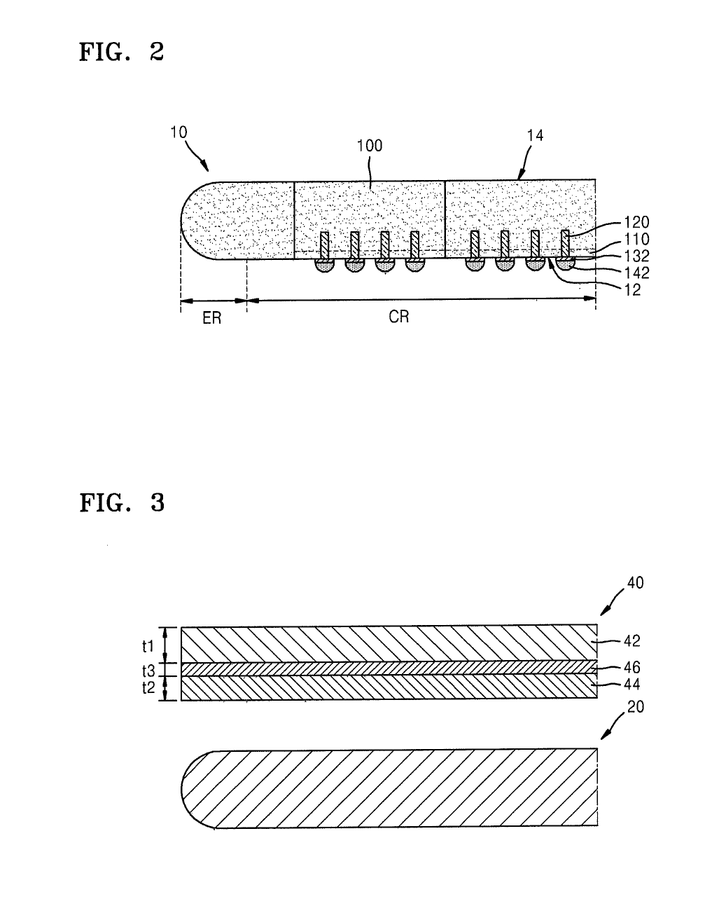

FIG. 2 is a cross-sectional view illustrating the semiconductor substrate 10 according to an embodiment of the inventive concepts. Specifically, FIG. 2 is a cross-sectional view taken along line A-A′ of FIG. 1.

Referring to FIGS. 1 and 2, the semiconductor substrate 10 may include the chip region CR, in which the plurality of semiconductor chips 100 are arranged, and the edge region ER that surrounds the chip region CR. In the chip region CR, portions adjacent to the edge region ER may be parts of the semiconductor chips 100 or may be a dummy space other than the semiconductor chips 100 in accordance with an arrangement of the semiconductor chips 100. That is, the chip region CR may be used as the semiconductor chips 100 or may not be used as the semiconductor chips 100 in accordance with a size, shape, and arrangement of the semiconductor chips 100.

In some embodiments, a thickness of the edge region ER may be reduced in a direction toward an edge thereof. A thickness of a portion adjacent to the edge of the edge region ER may be smaller than that of the chip region CR toward the edge of the edge region ER. The edge region ER may be referred to as a bevel region. In addition, a level difference that occurs because the thickness of the edge region ER is reduced toward the edge thereof may be referred to as a bevel level difference.

In some embodiments, the semiconductor chips 100 include device regions 110 in which the plurality of individual devices are formed on an active surface 12. Each of the plurality of semiconductor chips 100 may include a plurality of through-silicon vias (TSVs) 120 that extend from the active surface 12 to an inner region of the semiconductor substrate 10. In some embodiments, the TSVs 120 are not exposed on a non-active surface 14 opposite the active surface 12 in a current process. However, the TSVs 120 may optionally later become through electrodes that pass through the semiconductor chip 100 in a subsequent process. The active surface 12 and the non-active surface 14 of the semiconductor substrate 10 may correspond with those of the semiconductor chips 100 included in the semiconductor substrate 10.

Each of the TSVs 120 may include a wiring line metal layer (not shown) and a barrier metal layer (not shown) that surrounds the wiring line metal layer. The wiring line metal layer may include copper (Cu) or tungsten (W). For example, in some embodiments, the wiring line metal layer may comprise Cu, copper tin (CuSn), copper magnesium (CuMg), copper nickel (CuNi), copper zinc (CuZn), copper palladium (CuPd), copper gold (CuAu), copper rhenium (CuRe), CuW, W, or a W alloy. However, the inventive concepts are not limited thereto. For example, in some embodiments, the wiring line metal layer may include one or more of aluminium (Al), Au, beryllium (Be), bismuth (Bi), cobalt (Co), Cu, hafnium (Hf), indium (In), manganese (Mn), molybdenum (Mo), Ni, lead (Pb), Pd, platinum (Pt), rhodium (Rh), rhenium (Re), ruthenium (Ru), tantalum (Ta), tellurium (Te), titanium (Ti), W, Zn, and zirconium (Zr) and may include one or more stacked structures. The barrier metal layer may include at least one material selected from W, tungsten nitride (WN), tungsten carbide (WC), Ti, titanium nitride (TiN), Ta, tantalum nitride (TaN), Ru, Co, Mn, Ni, and nickel boride (NiB) and may be formed of a single layer or layers. However, the inventive concepts are not limited thereto. The barrier metal layer and the wiring line metal layer may be formed by a physical vapor deposition (PVD) process or a chemical vapor deposition (CVD) process. However, the inventive concepts are not limited thereto. In some embodiments, a spacer insulating layer (not shown) may be interposed between the TSVs 120 and the semiconductor substrate 10. The spacer insulating layer may prevent the device regions 110 from directly contacting the TSVs 120. In some embodiments, the spacer insulating layer may be formed of an oxide film, a nitride film, a carbide film, polymer, or a combination thereof. In some embodiments, a CVD process may be used for forming the spacer insulating layer. The spacer insulating layer may be formed of an ozone/tetra-ethyl ortho-silicate (O₃/TEOS) based high aspect ratio process (HARP) oxide film formed by a sub-atmospheric CVD process.

The TSVs 120 are illustrated as having a via-last structure in which the TSVs 120 extend from the active surface 12 to interior region of the semiconductor substrate 10. However, the inventive concepts are not limited thereto. The TSVs 120 may have at least one of a via-first structure, a via-middle structure, and the via-last structure. Since the via-first structure, the via-middle structure, and the via-last structure and methods of manufacturing the same are disclosed in documents including books such as Three Dimensional System Integration, published by Springer in 2011, 3D Integration for VLSI Systems, published by CRC Press in 2012, and Designing TSVs for 3D Integrated Circuits, published by Springer in 2013, detailed description thereof will not be given.

A plurality of front surface pads 132 corresponding to the plurality of TSVs 120, respectively, may be formed on the active surface 120 of the semiconductor chips 100. In addition, connection bumps 142 may be formed on the front surface pads 132, respectively. Under bump metals (UBM) may be formed on the front surface pads 132, respectively.

The front surface pads 132 may be formed of Al or Cu by pulse plating or direct current (DC) plating. However, inventive concepts are not limited thereto.

The connection bumps 142 may be provided on the front surface pads 132, respectively. In some embodiments, the connection bumps 142 may be formed of a conductive material such as Cu, Al, silver (Ag), Sn, Au, and solder. However, the inventive concepts are not limited thereto. The connection bumps 142 may be formed of multiple layers or a single layer. For example, the connection bumps 142 may include Cu pillars and solder when the connection bumps 142 are formed of layers and may be formed of Sn—Ag solder or Cu when the connection bumps 142 are formed of a single layer.

Unless otherwise defined, the cross-sectional views described hereinafter illustrate portions corresponding to those of the cross-sectional view of the semiconductor substrate 10 illustrated in FIG. 2.

FIGS. 3 to 8 are cross-sectional views illustrating processes of a method of manufacturing a semiconductor device, according to an embodiment of the inventive concepts.

FIG. 3 is a cross-sectional view illustrating a process of preparing a support substrate 20 and an adhesive support film 40 according to an embodiment of the inventive concepts.

Referring to FIG. 3, the support substrate 20 and the adhesive support film 40 are prepared.

In some embodiments, the support substrate 20 may have a size (an area) that is equal to or larger than that of the semiconductor substrate 10 illustrated in FIGS. 1 and 2. In some embodiments, the support substrate 20 may comprise, for example, a semiconductor wafer or a glass substrate.

A thickness of the support substrate 20 may be reduced toward an edge thereof, for example as shown. Since a change in thickness of the support substrate 20 is the same as, or similar to, that of the edge region ER of the semiconductor substrate 10 illustrated in FIG. 2, detailed description thereof will not be given.

The adhesive support film 40 includes a base film 46 and a first adhesive layer 42 and a second adhesive layer 44 attached respectively to both surfaces of the base film 46. The base film 46 may be in a C-stage state. In some embodiments, the first adhesive layer 42 and the second adhesive layer 44 may be in a B-stage state. Here, in the B-stage state, a solvent used in an A-stage state that is an initial reaction process of thermoplastic resin is removed, however, the thermoplastic resin is not hardened. In the B-stage state, the thermoplastic resin is not melted and is swollen and is not dissolved by the solvent. Therefore, the A-stage state is commonly changed into the B-stage stage through thermal processing. In the B-stage state, the thermoplastic resin may be adhesive. In the C-stage state, the thermoplastic resin is completely hardened.

In some embodiments, the base film 46 may comprise, for example, a polyethylene-based film or a polyolefin-based film such as polyethylene terephthalate (PET) or polyethylene-2,6-naphthalenedicarboxylate (PEN). The base film 46 may be formed by coating the polyethylene-based film or coating the polyolefin-based film with silicon or Teflon.

In some embodiments, the first adhesive layer 42 and the second adhesive layer 44 may be formed of the same material. The first adhesive layer 42 and the second adhesive layer 44 may be formed of, for example, acryl-based polymer resin, epoxy resin, or a combination thereof.

The first adhesive layer 42 may be formed to be relatively thick to surround the front surface pads 132 and the connection bumps 142 illustrated in FIG. 2, compared to the second adhesive layer 44 and the base film 46. In some embodiments, a first thickness t1 of the first adhesive layer 42 may be larger than a second thickness t2 of the second adhesive layer 44. In some embodiments, the first thickness t1 of the first adhesive layer 42 may be larger than a third thickness t3 of the base film 46. For example, when heights of the front surface pads 132 and the connection bumps 142 are several tens of the first thickness t1 may be no less than 100 μm. The second thickness t2 or the third thickness t3 may be, for example, several tens of μm.

The elastic modulus of the base film 46 may be larger than those of the first adhesive layer 42 and the second adhesive layer 44. In some embodiments, the first adhesive layer 42 and the second adhesive layer 44 may have a Young's modulus of no more than several tens of MPa, for example, from several to several tens of MPa. In some embodiments, the base film 46 may have a Young's modulus of no less than several GPa, for example, from several to several tens of GPa.

Although described later, the first adhesive layer 42 may adhere to the semiconductor substrate 10 illustrated in FIGS. 1 and 2 and the second adhesive layer 44 may adhere to the support substrate 20. Therefore, the first adhesive layer 42 and the second adhesive layer 44 may be referred to as the semiconductor substrate adhesive layer 42 and the support substrate adhesive layer 44, respectively.

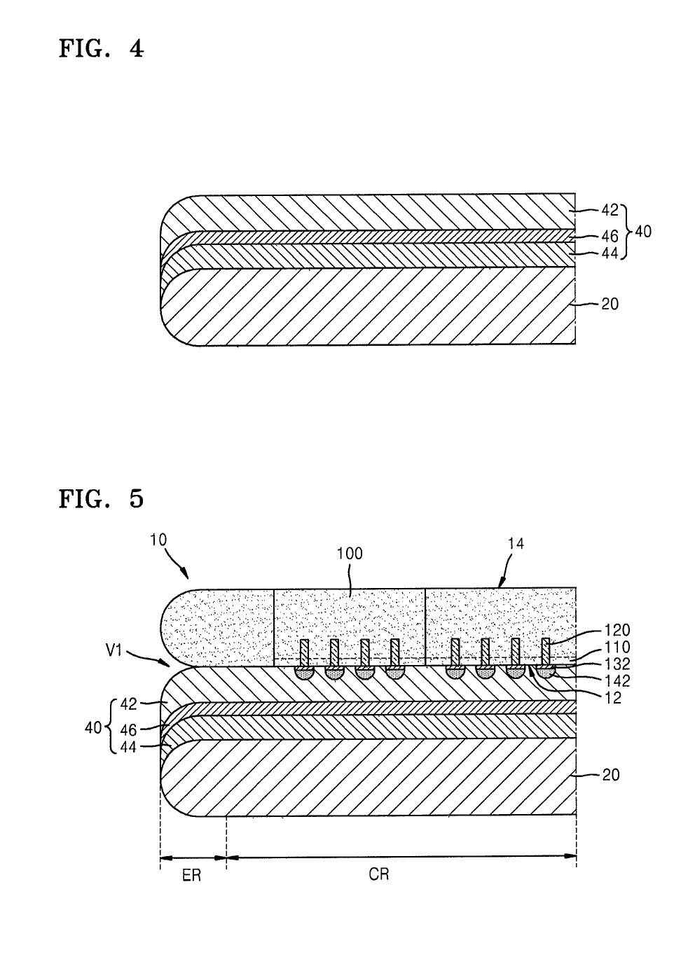

FIG. 4 is a cross-sectional view illustrating a process of attaching the adhesive support film 40 to the support substrate 20 according to an embodiment of the inventive concepts.

Referring to FIG. 4, the adhesive support film 40 is attached to the support substrate 20. The adhesive support film 40 may be attached to the support substrate 20 so that the second adhesive layer 44 faces the support substrate 20.

The adhesive support film 40 may be attached onto the support substrate 20 to cover an entire upper surface of the support substrate 20. Due to a level difference that occurs because the thickness of the support substrate 20 is reduced toward the edge thereof, a level difference may occur on an upper surface of the adhesive support film 40, that is, an upper surface of the first adhesive layer 42.

FIG. 5 is a cross-sectional view illustrating a process of attaching the semiconductor substrate 10 to the support substrate 20 by using the adhesive support film 40, according to an embodiment of the inventive concepts.

Referring to FIG. 5, the semiconductor substrate 10 is attached to the support substrate 20 by using the adhesive support film 40. The semiconductor substrate 10 may be attached to the first adhesive layer 42 of the adhesive support film 40. In some embodiments, the semiconductor substrate 10 may be attached to the support substrate 20 so that the active surface 12 faces the support substrate 20.

The front surface pads 132 and the connection bumps 142 formed on the active surface 12 of the semiconductor chips 100 may be partially surrounded, on their exposed surfaces, by the first adhesive layer 42. Therefore, on the active surface 12 of the semiconductor substrate 10, portions on which the front surface pads 132 and the connection bumps 142 are not formed of the active surface 12 may contact the first adhesive layer 42.

Due to the level difference that occurs at the edge region ER of the semiconductor substrate 10 and the level difference that occurs on the upper surface of the adhesive support film 40, a space V1 may be formed between the semiconductor substrate 10 and the adhesive support film 40, which corresponds to the edge region ER of the semiconductor substrate 10.

That is, when an area of the support substrate 20 is actually equal to that of the semiconductor substrate 10 and the thickness of the edge region ER of the semiconductor substrate 10 and that of the edge of the support substrate 20 corresponding to the edge region ER of the semiconductor substrate 10 are reduced toward the edge region ER of the semiconductor substrate 10 and the edge of the support substrate 20, due to the level difference that occurs at the edge region ER of the semiconductor substrate 10 and the level difference that occurs on the upper surface of the adhesive support film 40, which is caused by the level difference that occurs at the edge of the support substrate 20, the space V1 may be formed between the semiconductor substrate 10 and the adhesive support film 40, which corresponds to the edge region ER of the semiconductor substrate 10.

When the space V1 is present between the semiconductor substrate 10 and the adhesive support film 40, in a later described process of polishing the semiconductor substrate 10 or forming rear surface pads on the semiconductor substrate 10, a portion adjacent to the edge of the semiconductor substrate 10 may become bent as a result of the process so that the edge of the semiconductor substrate 10 may be caused to crack. When the edge of the semiconductor substrate 10 cracks, the semiconductor chip 100 adjacent to the edge of the semiconductor substrate 10 or the entire semiconductor substrate 10 may be damaged by the crack, thereby adversely affecting process yield.

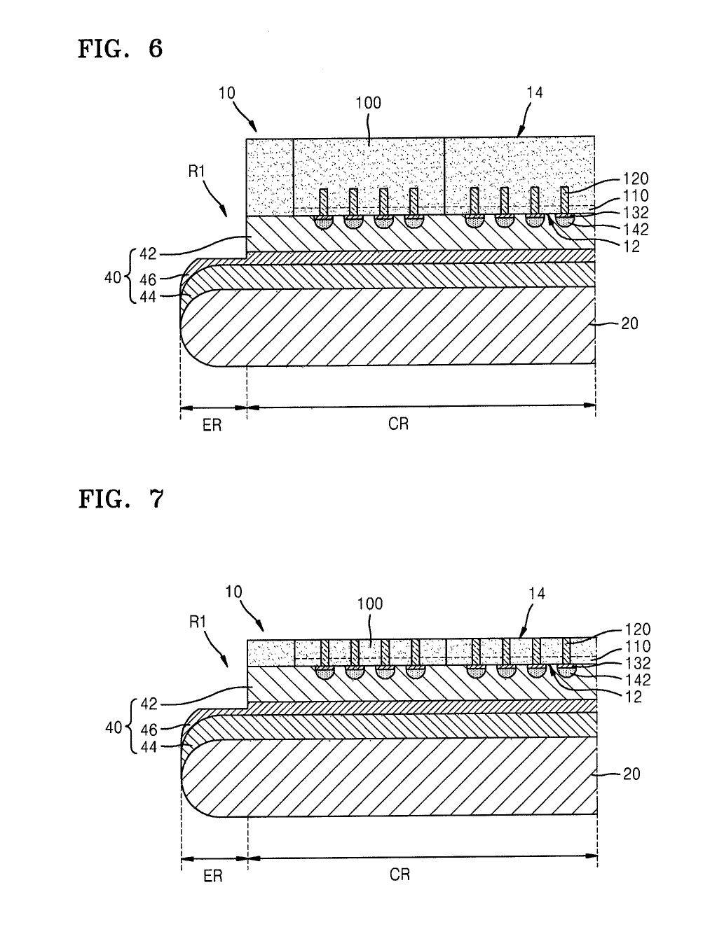

FIG. 6 is a cross-sectional view illustrating a process of trimming the semiconductor substrate 10, according to an embodiment of the inventive concepts.

Referring to FIG. 6, a trimming process for removing the edge region ER of the semiconductor substrate 10 is performed. When the edge region ER of the semiconductor substrate 10 is removed, a portion of the adhesive support film 40 between the edge region ER of the semiconductor substrate 10 and the support substrate 20 is also removed so that a removal space R1 may be formed along the edge of the semiconductor substrate 10. In this manner, the space V1 between the semiconductor substrate 10 and the adhesive support film 40, which is illustrated in FIG. 5, may be removed.

In some embodiments, the trimming process for removing the edge region ER of the semiconductor substrate 10 may be performed by an etching process or a blade saw method. The trimming process may be performed until the base film 46 is exposed by using the base film 46 as an etching stop film. As a result of the trimming process, at least a part of the base film 46 may remain on the second adhesive layer 44 of the adhesive support film 40 between the edge region ER of the semiconductor substrate 10 and the support substrate 20. Therefore, although the edge region ER of the semiconductor substrate 10 and a portion of the first adhesive layer 42 corresponding thereto are removed, an upper surface of the second adhesive layer 44 may be covered with the base film 46 thereby not to be exposed.

FIG. 7 is a cross-sectional view illustrating a process of polishing a semiconductor substrate to thin the semiconductor substrate, according to an embodiment of the inventive concepts.

Referring to FIG. 7, in some embodiments, a grinding process for polishing the semiconductor substrate 10 to thin the semiconductor substrate 10, that is, a back-lap process, is performed. In the grinding process, the semiconductor substrate 10 is polished from the non-active surface 14 opposite to the active surface 12 of the semiconductor substrate 10 so that the TSVs 120 of the semiconductor chips 100 may be exposed. In some embodiments, the semiconductor substrate 10 has a thickness of no less than several hundreds of μm and may be thinned to have a thickness of 100 μm or so or a thickness of several tens of μm by the grinding process. The support substrate 20 may support the semiconductor substrate 10 while polishing the semiconductor substrate 10 to thin the semiconductor substrate 10. The grinding process may be performed by, for example, a chemical mechanical polishing (CMP) process, an etch-back process, or a combination thereof.

As illustrated in FIG. 5, when the space V1 is present between the semiconductor substrate 10 and the adhesive support film 40, the semiconductor substrate 10 may be bent to be cracked by pressure applied to the semiconductor substrate 10 while performing the grinding process. However, as illustrated in FIG. 6, when the space V1 between the semiconductor substrate 10 and the adhesive support film 40 is removed by the trimming process, since the semiconductor substrate 10 is not bent by pressure applied to the semiconductor substrate 10 while performing the grinding process; therefore, the semiconductor chips 100 or the semiconductor substrate 10 are not damaged, thereby improving manufacturing yield.

In addition, the semiconductor substrate 10 may be even further thinned so that a pitch of the TSVs 120 may be reduced. Therefore, it is possible to implement a wide I/O design.

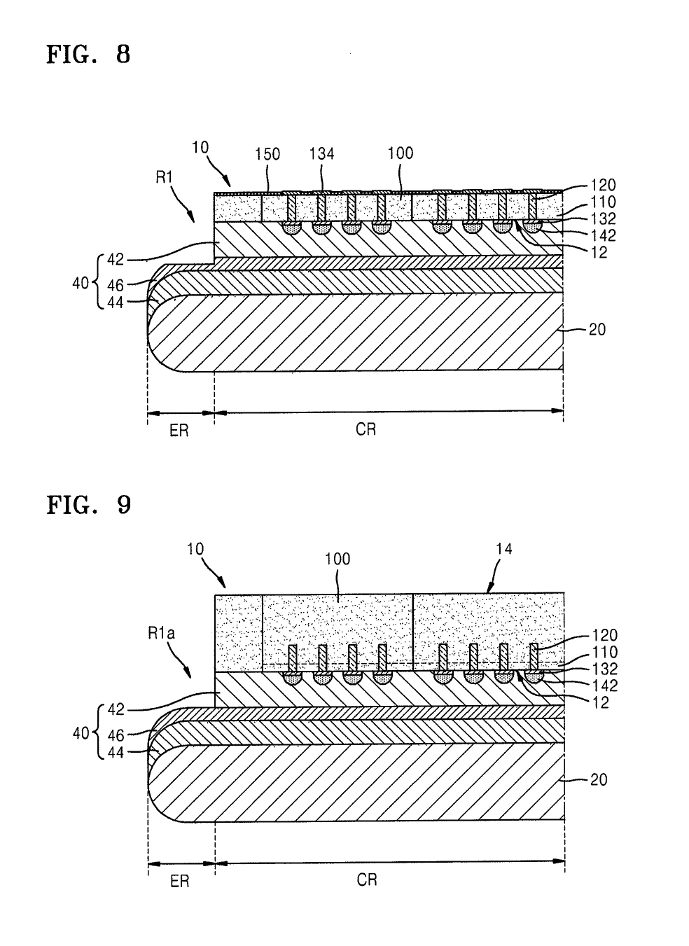

FIG. 8 is a cross-sectional view illustrating a process of forming rear surface pads on a semiconductor substrate, according to an embodiment of the inventive concepts.

Referring to FIG. 8, a rear surface protective layer 150 that covers the non-active surface 14 of the semiconductor substrate 10 and exposes the TSVs 120 is formed. The rear surface protective layer 150 may be formed by, for example, a spin coating process or a spray process. The rear surface protective layer 150 may be formed of, for example, polymer. The rear surface protective layer 150 may be formed by, after forming a polymer film that completely covers the non-active surface 14 of the semiconductor substrate 10 and the exposed portions of the TSVs 120, partially etching back the polymer film to expose the TSVs 120.

After forming the rear surface protective layer 150, rear surface pads 134 may be formed on the non-active surface 14 of the semiconductor chips 100 and be electrically connected to the TSVs 120, respectively. The rear surface pads 134 may be formed after forming the rear surface protective layer 150. However, after forming the rear surface pads 134, the rear surface protective layer 150 may be formed to expose the rear surface pads 134, rather than the TSVs 120.

FIG. 9 is a cross-sectional view illustrating a process of trimming a semiconductor substrate, according to a modification of an embodiment of the inventive concepts. Specifically, since FIG. 9 is a cross-sectional view illustrating a process subsequent to that of FIG. 5 and corresponding to that of FIG. 6, repeated description thereof will not be given.

Referring to FIG. 9, a trimming process of removing the edge region ER of the semiconductor substrate 10 is performed. When the edge region ER of the semiconductor substrate 10 is removed, a part of the adhesive support film 40 between the edge region ER of the semiconductor substrate 10 and the support substrate 20 is also removed so that a removal space R1a may be formed along the edge of the semiconductor substrate 10. Therefore, the space V1 between the semiconductor substrate 10 and the adhesive support film 40, which is illustrated in FIG. 5, may be removed.

Unlike in FIG. 6, in the trimming process of removing the edge region ER of the semiconductor substrate 10 illustrated in FIG. 9, the edge region ER of the semiconductor substrate 10 and a portion of the first adhesive layer 42 corresponding thereto are removed, however, as shown in the present embodiment, the entire base film 46 may remain.

The trimming process of removing the edge region ER of the semiconductor substrate 10 may be performed by an etching process or a blade saw method. For example, after removing the edge region ER of the semiconductor substrate 10 and a part of the first adhesive layer 42 thereunder by a blade saw method, the first adhesive layer 42 is removed until the base film 46 is exposed through the etching process so that the entire base film 46 may remain. Therefore, it is possible to prevent the upper surface of the second adhesive layer 44 from being exposed.

Then, as illustrated in FIGS. 7 and 8, in some embodiments, the grinding process of thinning the semiconductor substrate 10 is performed and the rear surface protective layer 150 and the rear surface pads 134 may be formed.

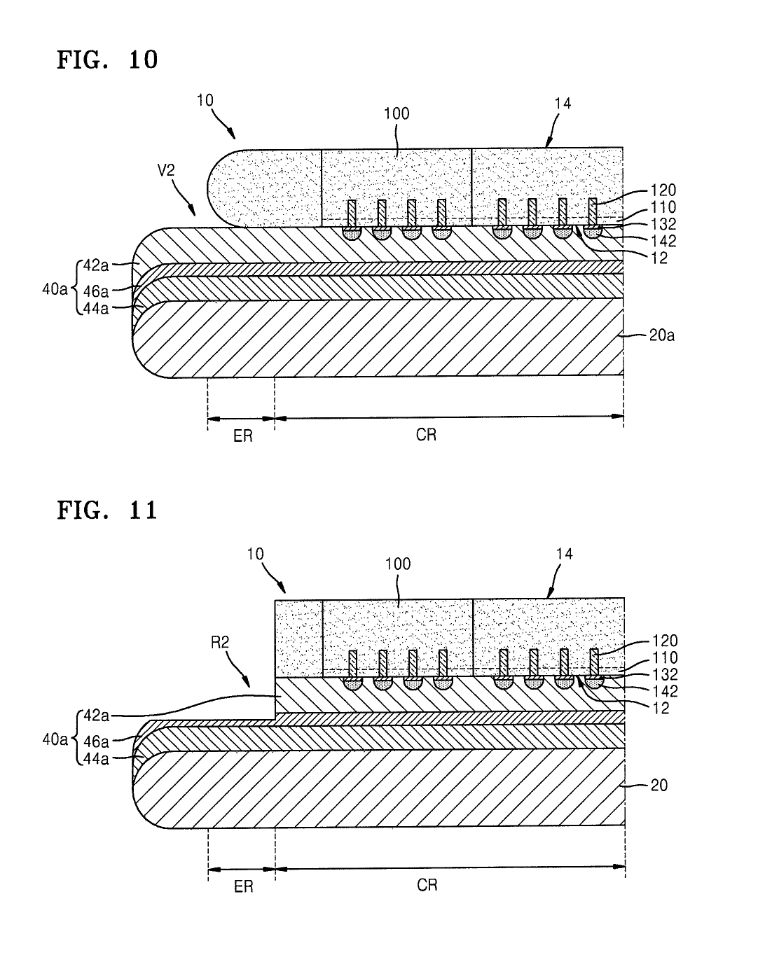

FIGS. 10 and 11 are cross-sectional views illustrating processes of a method of manufacturing a semiconductor device, according to another modification of an embodiment of the inventive concepts. Specifically, since FIGS. 10 and 11 are the same as FIGS. 5 and 6, except that areas of a support substrate 20a and an adhesive support film 40a are larger than those of the support substrate 20 and the adhesive support film 40 illustrated in FIGS. 5 and 6, repeated description thereof will not be given.

FIG. 10 is a cross-sectional view illustrating a process of attaching a semiconductor substrate to a support substrate by using an adhesive support film, according to another modification of an embodiment of the inventive concepts.

Referring to FIG. 10, in some embodiments, the semiconductor substrate 10 is attached to the support substrate 20a by using the adhesive support film 40a. In some embodiments, the semiconductor substrate 10 may be attached to a first adhesive layer 42a of the adhesive support film 40a.

The area of the support substrate 20a and that of the adhesive support film 40a may be larger than that of the semiconductor substrate 10. Therefore, the semiconductor substrate 10 may be attached onto an upper surface of the adhesive support film 40a in a portion where a level difference does not occur, for example, where an upper surface of the adhesive support film 40a is relatively flat. Therefore, a space V2 present between the semiconductor substrate 10 and the adhesive support film 40a, which corresponds to the edge region ER of the semiconductor substrate 10, may be smaller than the space V1 present between the semiconductor substrate 10 and the adhesive support film 40, which is illustrated in FIG. 5.

FIG. 11 is a cross-sectional view illustrating a process of trimming a semiconductor substrate, according to another modification of an embodiment of the inventive concepts.

Referring to FIG. 11, a trimming process for removing the edge region ER of the semiconductor substrate 10 is performed. When the edge region ER of the semiconductor substrate 10 is removed, a portion of the adhesive support film 40a between the edge region ER of the semiconductor substrate 10 and the support substrate 20a is also removed so that a removal space R2 may be formed along the edge of the semiconductor substrate 10. Therefore, the space V2 between the semiconductor substrate 10 and the adhesive support film 40a, which is illustrated in FIG. 10, may be removed.

A part of a base film 46a may also be removed by the trimming process. However, an upper surface of a second adhesive layer 44a may be covered with the base film 46a not to be exposed.

In addition, although not shown, like in FIG. 9, the trimming process may be performed so that the edge region ER of the semiconductor substrate 10 and a portion of the first adhesive layer 42a corresponding thereto are removed. However, in some embodiments, the entire base film 46a may remain.

Then, as illustrated in FIGS. 7 and 8, the grinding process for thinning the semiconductor substrate 10 is performed and the rear surface protective layer 150 and the rear surface pads 134 may be formed.

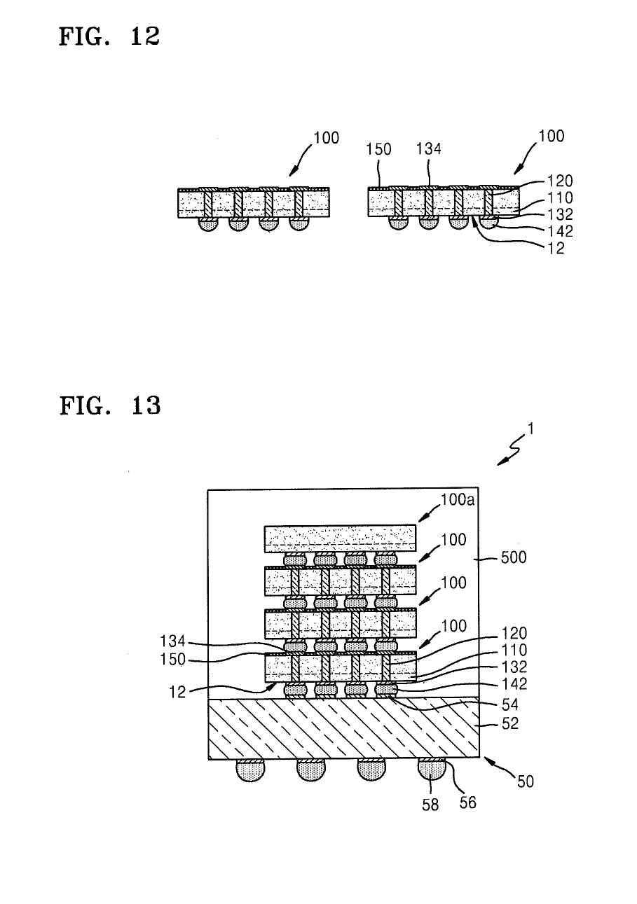

FIG. 12 is a cross-sectional view illustrating semiconductor chips according to an embodiment of the inventive concepts. Specifically, since the semiconductor chips 100 illustrated in FIG. 12 may be formed by the manufacturing methods described with reference to FIGS. 3 to 8, 9, 10, and 11, description thereof will be made with reference to FIGS. 3 to 8, 9, 10, 11, and 12.

Referring to FIGS. 8 and 12, after forming the rear surface protective layer 150 and the rear surface pads 134 on the non-active surface 14 of the semiconductor substrate 10, the semiconductor substrate 10 is separated from the support substrate 20. Then, a die sawing process of separating the plurality of semiconductor chips 100 included in the semiconductor substrate 10 from each other is performed.

In order to perform the die sawing process, after attaching the semiconductor substrate 10 to a dicing film (not shown), the plurality of semiconductor chips 100 may be partially or completely cut off at spaces by a laser saw method, a laser stealth saw method, or a blade saw method. Then, the dicing film is extended to separate the semiconductor chips 100 from each other.

In order to perform the die sawing process, after separating the semiconductor substrate 10 from the support substrate 20 together with the adhesive support film 40, in some embodiments, the semiconductor chips 100 may be separated from each other by using the adhesive support film 40 as the dicing film.

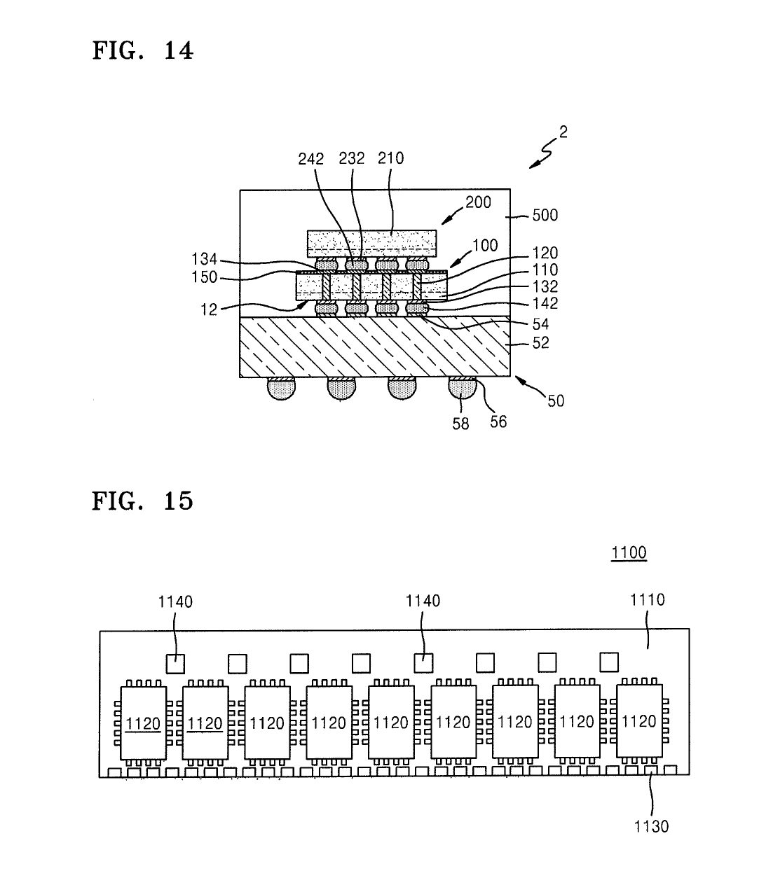

FIGS. 13 and 14 are cross-sectional views illustrating a stacked semiconductor package 1 including a semiconductor device, according to an embodiment of the inventive concepts.

FIG. 13 is a cross-sectional view illustrating an aspect of the stacked semiconductor package 1 including a semiconductor device, according to an embodiment of the inventive concepts.

Referring to FIG. 13, the stacked semiconductor package 1 includes a plurality of semiconductor chips 100 and 100a stacked on a package base substrate 50 and electrically connected to the package base substrate 50. A molding layer 500, including the plurality of semiconductor chips 100 and 100a, may be formed on the package base substrate 50. In some embodiments, the molding layer 500 may be formed of, for example, epoxy mold compound (EMC).

In some embodiments, the molding layer 500 may cover an entire upper surface of the package base substrate 50. However, the inventive concepts are not limited thereto. The molding layer 500 may expose a part of the upper surface of the package base substrate 50. The molding layer 500 may optionally cover an upper surface of the uppermost semiconductor chip 100a. However, the inventive concepts are not limited thereto. The molding layer 500 may surround side surfaces of the uppermost semiconductor chip 100a and may expose the upper surface of the uppermost semiconductor chip 100a. When the upper surface of the uppermost semiconductor chip 100a is exposed by the molding layer 500, the upper surface of the uppermost semiconductor chip 100a may be used as a path through which heat generated in the stacked semiconductor package 1 is emitted. A heat sink (not shown) may be selectively attached onto the upper surface of the uppermost semiconductor chip 100a.

The plurality of semiconductor chips 100 and 100a may be stacked so that device regions 110 face the package base substrate 50. It is illustrated that the uppermost semiconductor chip 100a of the plurality of semiconductor chips 100 and 100a does not include TSVs. However, the inventive concepts are not limited thereto. All of the plurality of semiconductor chips 100 and 100a or all of the plurality of semiconductor chips 100 and 100a except the uppermost semiconductor chip 100a include the TSVs 120 to be electrically connected to semiconductor chips thereon, respectively.

The plurality of semiconductor chips 100 and 100a may be the same kind of semiconductor devices actually having relatively the same area, respectively. For example, the plurality of semiconductor chips 100 and 100a may be volatile memory semiconductor chips such as dynamic random access memories (DRAM) or static random access memories (SRAM) or non-volatile memory semiconductor chips such as phase-change random access memories (PRAM), magneto-resistive random access memories (MRAM), ferroelectric random access memories (FeRAM), and resistive random access memories (RRAM).

The package base substrate 50 may comprise, for example, a printed circuit board (PCB), a ceramic substrate, or a lead frame. When the package base substrate 50 is a PCB, the package base substrate 50 may include a substrate base 52 and upper surface pads 54 and lower surface pads 56 formed on upper and lower surfaces thereof, respectively. The upper surface pads 54 and the lower surface pads 56 may be exposed by a solder resist layer (not shown) that covers upper and lower surfaces of the substrate base 52.

The substrate base 52 may be formed of at least one material selected from phenol resin, epoxy resin, and polyimide. For example, the substrate base 52 may include at least one material selected from FR4, tetrafunctional epoxy, polyphenylene ether, epoxy/polyphenylene oxide, bismaleimide triazine (BT), thermount, cyanate ester, polyimide, and liquid crystal polymer.

The upper surface pads 54 and the lower surface pads 56 may be formed of copper (Cu), nickel (Ni), stainless steel, or beryllium copper (BeCu). An internal wiring line (not shown) for electrically connecting the upper surface pads 54 and the lower surface pads 56 may be formed in the substrate base 52. The upper surface pads 54 and the lower surface pads 56 may be portions exposed by the solder resist layer (not shown) in a circuit wiring line patterned after the upper and lower surfaces of the substrate base 52 are coated with Cu foil. External connection terminals 58 may be respectively attached onto the lower surface pads 56 formed on the lower surface of the package base substrate 50. The external connection terminals 58 may be, for example, solder balls and bumps. The external connection terminals 58 may electrically connect the stacked semiconductor package 1 and an external apparatus.

FIG. 14 is a cross-sectional view illustrating another aspect of a stacked semiconductor package 2 including a semiconductor device, according to an embodiment of the inventive concepts. In FIG. 14, descriptions that are the same as those made with reference to FIG. 13 will not be given.

Referring to FIG. 14, the stacked semiconductor package 2 includes an upper semiconductor chip 200 stacked on a package base substrate 50, electrically connected to the package base substrate 50 through a semiconductor chip 100 and TSVs 120, and stacked on the semiconductor chip 100. The semiconductor chip 100 and the upper semiconductor chip 200 may be different kinds of semiconductor chips and may have different areas. The semiconductor chip 100 may be, for example, a volatile or non-volatile memory semiconductor chip, a system LSI, or a system on chip (SoC). The upper semiconductor chip 200 may be, for example, a volatile or non-volatile memory semiconductor chip.

FIG. 15 is a plan view illustrating a memory module 1100 including a semiconductor device, according to an embodiment of the inventive concepts.

Referring to FIG. 15, the memory module 1100 includes a module substrate 1110 and a plurality of semiconductor chips 1120 attached to the module substrate 1110.

The semiconductor chip 1120 includes a semiconductor device or a stacked semiconductor package according to an embodiment of the inventive concepts. For example, the semiconductor chip 1120 may include the semiconductor chip 100 illustrated in FIG. 12 or the stacked semiconductor package 1 or 2 illustrated in FIG. 13 or 14.

In some embodiments, connection units 1130 that may be inserted into sockets of a mother board are arranged on one side of the module substrate 1110. Ceramic decoupling capacitors 1140 are arranged on the module substrate 1110. The memory module 1100 according to the inventive concepts is not limited to the structure illustrated in FIG. 15 and may be manufactured in various forms.

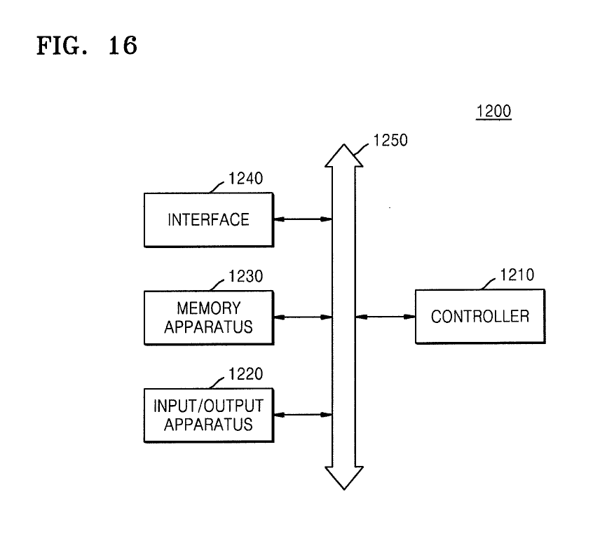

FIG. 16 is a block diagram of a system including a semiconductor device, according to an embodiment of the inventive concepts.

Referring to FIG. 16, the system 1200 includes a controller 1210, an input/output apparatus 1220, a memory apparatus 1230, and an interface 1240. The system 1200 may be a mobile system or a system for transmitting or receiving information. In some embodiments, the mobile system is a personal digital assistant (PDA), a portable computer, a web tablet, a wireless phone, a mobile phone, a digital music player, or a memory card. The controller 1210 for controlling an execution program in the system 1200 may be formed of a microprocessor, a digital signal processor, a microcontroller, or a similar apparatus. The controller 1210 may include a semiconductor device or a stacked semiconductor package according to an embodiment of the inventive concepts. For example, the controller 1210 may include the semiconductor chip 100 illustrated in FIG. 12 or the stacked semiconductor package 2 illustrated in FIG. 14.

The input/output apparatus 1220 may be used for inputting or outputting data of the system 1200. The system 1200 is connected to an external apparatus, for example, a personal computer (PC) or a network by using the input/output apparatus 1220 and may exchange data with the external apparatus. The input/output apparatus 1220 may comprise, for example, a keypad, a keyboard, or a display.

The memory apparatus 1230 may store a code and/or data for operating the controller 1210 or may store data processed by the controller 1210. The memory apparatus 1230 may include a semiconductor device or a stacked semiconductor package according to an embodiment of the inventive concepts. For example, the memory apparatus 1230 may include the semiconductor chip 100 illustrated in FIG. 12 or the stacked semiconductor package 1 or 2 illustrated in FIG. 13 or 14.

The interface 1240 may comprise a transmission channel between the system 1200 and another external apparatus. The controller 1210, the input/output apparatus 1220, the memory apparatus 1230, and the interface 1240 may communicate with each other through a bus 1250. In various embodiments, the system 1200 may be used for a mobile phone, an MP3 player, a navigator, a portable multimedia player (PMP), a solid state disk (SSD), or household appliances.

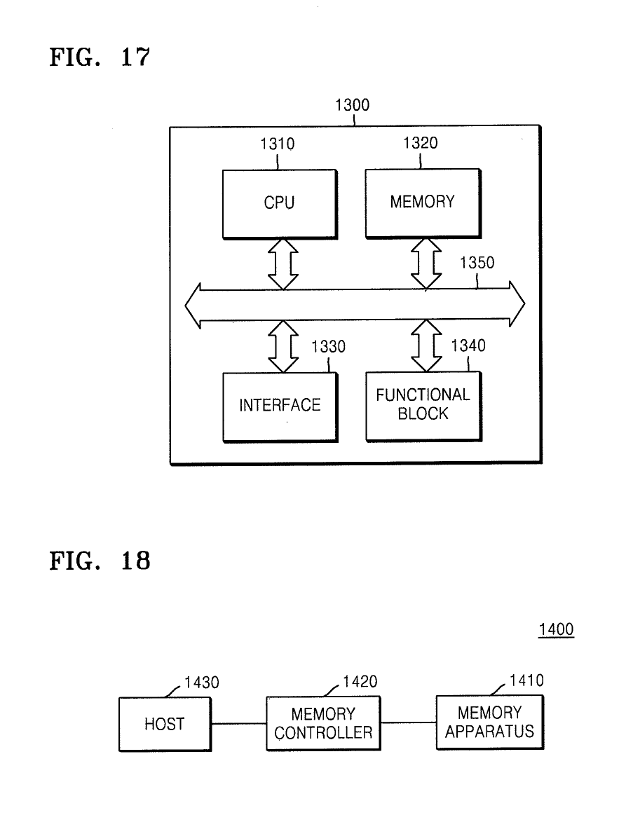

FIG. 17 is a view schematically illustrating a structure of a stacked semiconductor package 1300 according to an embodiment of the inventive concepts.

Referring to FIG. 17, the stacked semiconductor package 1300 may include a SoC. The stacked semiconductor package 1300 may include a central processing unit (CPU) 1310, a memory 1320, an interface 1330, a functional block 1340, and a bus 1350 for connecting the CPU 1310, the memory 1320, the interface 1330, and the functional block 1340. The CPU 1310 may control an operation of the SoC. The CPU 1310 may include cores and an L2 cache. For example, the CPU 1310 may include a multi-core. Cores of the multi-core may have the same performance or different performances. In addition, the cores of the multi-core may be simultaneously activated or may be activated at different points of time. The memory 1320 may store a result processed by the functional block 1340 by control of the CPU 1310. For example, content stored in the L2 cache of the CPU 1310 may be flushed and be stored in the memory 1320. The interface 1330 may interface with external apparatuses. For example, the interface 1330 may interface with a camera, a liquid crystal display (LCD), and a speaker.

The functional block 1340 may perform various functions required by the SoC. Although one functional block 1340 is included, the stacked semiconductor package 1300 may include a plurality of functional blocks 1340. For example, when the stacked semiconductor package 1300 is an application processor (AP) used for a mobile apparatus, some of the plurality of functional blocks 1340 may perform a communication function.

The stacked semiconductor package 1300 includes a semiconductor device or a stacked semiconductor package according to an embodiment of the inventive concepts. For example, the stacked semiconductor package 1300 may include the semiconductor chip 100 illustrated in FIG. 12 or the stacked semiconductor package 2 illustrated in FIG. 14.

The memory 1120 may include a semiconductor device or a stacked semiconductor package according to an embodiment of the inventive concepts. For example, the memory 1120 may include the semiconductor chip 100 illustrated in FIG. 12 or the stacked semiconductor package 1 or 2 illustrated in FIG. 13 or 14.

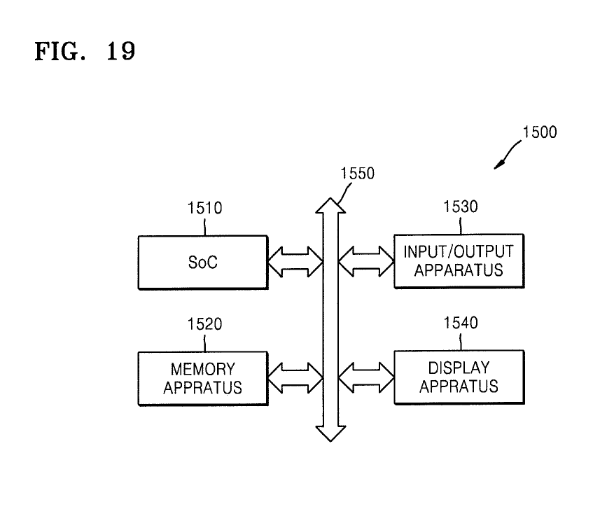

FIG. 18 is a block diagram of a memory card 1400 including a semiconductor device, according to an embodiment of the inventive concepts.

Referring to FIG. 18, the memory card 1400 includes a memory apparatus 1410 and a memory controller 1420.

The memory apparatus 1410 may store data. In some embodiments, the memory apparatus 1410 is non-volatile so that stored data may be maintained although a power supply is stopped. The memory apparatus 1410 includes a semiconductor device or a stacked semiconductor package according to an embodiment of the inventive concepts. For example, the memory apparatus 1410 may include the semiconductor chip 100 illustrated in FIG. 12 or the stacked semiconductor package 1 or 2 illustrated in FIG. 13 or 14.

The memory controller 1420 may read data stored in the memory apparatus 1410 or may store data in the memory apparatus 1410 in response to a read/write request of a host 1430.

FIG. 19 is a view illustrating an electronic system 1500 including a semiconductor device, according to an embodiment of the inventive concepts.

Referring to FIG. 19, a SoC 1510 may be mounted in the electronic system 1500. The electronic system 1500 may be, for example, a mobile apparatus, a desktop computer, or a server. In addition, the electronic system 1500 may further include a memory apparatus 1520, an input/output apparatus 1530, and a display apparatus 1540 that may be electrically connected to a bus 1550. The SoC 1510 includes a semiconductor device or a stacked semiconductor package according to an embodiment of the inventive concepts. For example, the SoC 1510 may include the semiconductor chip 100 illustrated in FIG. 12 or the stacked semiconductor package 2 illustrated in FIG. 14. The memory apparatus 1520 may include a semiconductor device or a stacked semiconductor package according to an embodiment of the inventive concepts. For example, the memory apparatus 1520 may include the semiconductor chip 100 illustrated in FIG. 12 or the stacked semiconductor package 1 or 2 illustrated in FIG. 13 or 14.

While the inventive concepts have been particularly shown and described with reference to exemplary embodiments thereof, it will be understood that various changes in form and details may be made therein without departing from the spirit and scope of the following claims.

What is claimed is:

1. A method of manufacturing a semiconductor device, the method comprising:
preparing a semiconductor substrate including a plurality of semiconductor chips;
attaching the semiconductor substrate to a support substrate with an adhesive support film;
removing an edge region of the semiconductor substrate together with a portion of the adhesive support film between the edge region of the semiconductor substrate and the support substrate; and
after removing the edge region of the semiconductor substrate, polishing the semiconductor substrate to thin the semiconductor substrate.

2. The method of claim 1,
wherein the adhesive support film comprises a base film and a first adhesive layer and a second adhesive layer respectively attached to upper and lower surfaces of the base film,
wherein the semiconductor substrate is attached to the first adhesive layer of the adhesive support film, and
wherein, in removing of the edge region of the semiconductor substrate together with a portion of the adhesive support film between the edge region of the semiconductor substrate and the support substrate, the first adhesive layer of the adhesive support film between the edge region of the semiconductor substrate and the support substrate is completely removed.

3. The method of claim 2, wherein, in removing of the edge region of the semiconductor substrate together with a portion of the adhesive support film between the edge region of the semiconductor substrate and the support substrate, a portion of the base film of the adhesive support film between the edge region of the semiconductor substrate and the support substrate is also removed.

4. The method of claim 2, wherein, in removing of the edge region of the semiconductor substrate together with a portion of the adhesive support film between the edge region of the semiconductor substrate and the support substrate, at least a portion of the base film remains on the second adhesive layer of the adhesive support film between the edge region of the semiconductor substrate and the support substrate.

5. The method of claim 2, wherein, in removing of the edge region of the semiconductor substrate together with a portion of the adhesive support film between the edge region of the semiconductor substrate and the support substrate, the edge region of the semiconductor substrate and the first adhesive layer are removed using a blade saw method so that an upper surface of the second adhesive layer is not exposed.

6. The method of claim 2, wherein an elastic modulus of the base film is larger than that of the first adhesive layer.

7. The method of claim 2, wherein a thickness of the first adhesive layer is larger than that of the base film.

8. The method of claim 1,
wherein, in the semiconductor substrate, each of the plurality of semiconductor chips comprises a plurality of through-silicon vias (TSV) that extend from an active surface of the semiconductor substrate to an inner region of the semiconductor substrate, and
wherein, in attaching of the semiconductor substrate to the support substrate by using the adhesive support film, the semiconductor substrate is attached to the support substrate so that the active surface of the semiconductor substrate faces the support substrate.

9. The method of claim 8, wherein, in polishing of the semiconductor substrate to thin the semiconductor substrate, the semiconductor substrate is polished from an opposite surface to the active surface thereof so that the plurality of TSVs are exposed.

10. The method of claim 9, wherein polishing of the semiconductor substrate to thin the semiconductor substrate further comprises:
forming a plurality of rear surface pads respectively corresponding to the plurality of exposed TSVs on the opposite surface to the active surface of the semiconductor substrate;
separating the semiconductor substrate from the support substrate; and
dividing the semiconductor substrate into the plurality of semiconductor chips by using die cutting.

11. The method of claim 1, wherein a thickness of the edge region of the semiconductor substrate is reduced toward an edge thereof.

12. A method of manufacturing a semiconductor device, the method comprising:
preparing a semiconductor substrate having a chip region in which a plurality of semiconductor chips are arranged and an edge region that surrounds the chip region;
attaching the semiconductor substrate to a support substrate by using an adhesive support film including a base film and a semiconductor substrate adhesive layer and a support substrate adhesive layer respectively attached to upper and lower surfaces of the base film;
removing the edge region of the semiconductor substrate and the semiconductor substrate adhesive layer thereunder to expose the base film; and
thereafter polishing the semiconductor substrate to thin the semiconductor substrate.

13. The method of claim 12, wherein, in removing of the edge region of the semiconductor substrate and the semiconductor substrate adhesive layer thereunder to expose the base film, the edge region of the semiconductor substrate and the semiconductor substrate adhesive layer are removed by using the base film as an etching stop film.

14. The method of claim 12, wherein an area of the support substrate is larger than that of the semiconductor substrate.

15. The method of claim 12,
wherein the area of the support substrate is substantially equal to that of the semiconductor substrate, and
wherein a thickness of the edge region of the semiconductor substrate and that of an edge region of the support substrate corresponding to the edge region of the semiconductor substrate are reduced toward an edge of the edge region of the semiconductor substrate and that of the edge region of the support substrate, respectively.

16. A method of manufacturing a semiconductor device, comprising:
preparing a semiconductor substrate having a chip region in a central region thereof and an edge region in a perimeter region thereof, the edge region surrounding the chip region;
attaching the semiconductor substrate to a support substrate using an adhesive support film;
removing the edge region of the semiconductor substrate to expose a portion of the adhesive support film,
following removing the edge region, polishing the semiconductor substrate to thin the semiconductor substrate.

17. The method of claim 16 wherein the adhesive support film includes a base film, and further includes a semiconductor substrate adhesive layer and a support substrate adhesive layer respectively attached to upper and lower surfaces of the base film.

18. The method of claim 17 wherein removing the edge region of the semiconductor substrate to expose a portion of the adhesive support film further comprises exposing a portion of the base film.

19. The method of claim 17 wherein removing the edge region of the semiconductor substrate to expose a portion of the adhesive support film comprises etching the edge region using a portion of the adhesive support film as an etch stop layer.

20. The method of claim 16,
wherein, following attaching the semiconductor substrate to a support substrate using an adhesive support film, and prior to removing the edge region of the semiconductor substrate to expose a portion of the adhesive support film, a gap is present at an edge portion between the semiconductor substrate and the adhesive support film, and
wherein removing the edge region of the semiconductor substrate to expose a portion of the adhesive support film removes the gap.
